(19) United States
(12) Patent Application Publication
(10) Pub. No.: US 2006/0292853 A1
(43) Pub. Date: Dec. 28, 2006

(54) Method for fabricating an integrated semiconductor circuit and semiconductor circuit

(75) Inventor: Rory Dickman, Graz (AT)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/158,318

(22) Filed: Jun. 22, 2005

(51) Int. Cl. H01L 21/4763

(52) U.S. Cl. 438/622

(57) ABSTRACT

The present invention relates to a method for fabricating an integrated semiconductor circuit having a conductor structure buried in a semiconductor substrate, and to an integrated semiconductor circuit, in which case the integrated semiconductor circuit may be an application specific semiconductor circuit or a semiconductor circuit that can be adapted for an application.

The present invention relates to a method for fabricating an integrated semiconductor circuit having a conductor structure buried in a semiconductor substrate, and to an integrated semiconductor circuit, in which case the integrated semiconductor circuit may be an application specific semiconductor circuit or a semiconductor circuit that can be adapted for an application.

Modern integrated semiconductor circuits contain a large number of electronic components and often integrate a wide variety of analog and digital functions. In this case, the fabrication costs are essentially determined by the number of fabrication steps, in particular by the number of photolithography masks, and by the area of the individual chip or the number of chips that can be processed on a wafer. Therefore, it is endeavored to produce the smallest possible chips with a least possible number of masks or fabrication steps.

Miniaturization generally requires, in particular, a space-saving accommodation of conductor structures via which potentials or voltages, currents and signals are effected between electrical, in particular electronic, components and also between the latter and connection contact areas provided for external connection. However, a space-saving arrangement of these conductor structures often necessitates a complex three-dimensional structure thereof, which can in turn only be produced with a high outlay, in particular with additional fabrication steps and lithography masks.

This high fabrication outlay has a particularly adverse effect if an integrated semiconductor circuit is to be adapted to a specific application by means of selected conductor structures, as occurs for example in the case of an ASIC (ASIC=application specific integrated circuit).

The object of the present invention is to provide a method for fabricating an integrated semiconductor circuit or an application specific integrated semiconductor circuit and also an integrated semiconductor circuit which enable a cost-effective fabrication of an integrated semiconductor circuit or of an application specific integrated semiconductor circuit.

This object is achieved by means of methods in accordance with claim 1 or 3 and an integrated semiconductor circuit in accordance with claim 19.

Preferred developments of the present invention are defined in the dependent patent claims.

In accordance with the present invention, in the case of a method for fabricating an integrated semiconductor circuit having a conductor structure buried in a semiconductor substrate, which conductor structure electrically conductively connects two connection regions, a semiconductor substrate is provided, in which two connection regions are produced. A preliminary structure—buried in the semiconductor substrate—for the conductor structure is produced between the two connection regions, the preliminary structure forming no electrically conductive connection or a connection of low electrical conductivity between the connection regions. Energy is supplied locally to the preliminary structure in order to convert the preliminary structure into the conductor structure, the conductor structure forming a connection between the connection regions whose electrical conductivity is higher than the conductivity of the connection formed by the preliminary structure.

In the case of a method for fabricating an application specific integrated semiconductor circuit in accordance with the present invention, provision is made of a semiconductor substrate with a plurality of electrical components. A plurality of preliminary structures buried in the semiconductor substrate are produced, each preliminary structure forming no electrically conductive connection or a connection of low electrical conductivity between two assigned connection regions. One or more of the preliminary structures are selected depending on an application for which the semiconductor circuit is provided. Energy is supplied locally to the one or more selected preliminary structures in order to convert them into a conductor structure or conductor structures which in each case form a connection between the assigned connection regions, the electrical conductivity of each conductor structure being higher than the conductivity of the connection formed by the preliminary structure. As a result, two electrical components are electrically conductively connected to one another.

An integrated semiconductor circuit in accordance with the present invention comprises a semiconductor substrate, two connection regions in the semiconductor substrate and a preliminary structure buried in the semiconductor substrate, which preliminary structure forms no electrically conductive connection or a connection of low electrical conductivity between the connection regions, and which preliminary structure can be converted into a buried conductor structure by local supply of energy, which buried conductor structure forms a connection between the two connection regions whose electrical conductivity is higher than the electrical conductivity of the connection formed by the preliminary structure.

The present invention is based on the idea of producing a conductor structure in two steps. In a first step, a preliminary structure is produced, which, at least in one section, has no or a low electrical conductivity, so that it forms no electrically conductive connection or a connection of low electrical conductivity between two connection regions. In a second step, energy is supplied locally to the preliminary structure, the supply of energy preferably being restricted to the preliminary structure or to its nonconductive section. This is achieved by means of focusing, by means of masks and/or by radiating in monochromatic electromagnetic radiation which is absorbed only by the preliminary structure but not by surrounding material. The energy supplied effects conversion of the preliminary structure into a conductor structure in which, in particular, the electrical conductivity is increased. The conversion of the preliminary structure into the conductor structure is effected thermally, for example, by diffusion of dopants, annealing of crystal lattice defects, mixing of mutually adjoining materials by diffusion, implementation of crystallization or recrystallization, or by a chemical reaction taking place at an interface between two materials. As an alternative, the energy supplied effects conversion of the preliminary structure into the conductor structure in a non-thermal manner, for example in a photochemical manner.

One advantage of the present invention consists in the fact that it enables a virtually arbitrary arrangement of conductor structures in the bulk of the semiconductor substrate and a virtually arbitrary form of each conductor structure. A space-saving arrangement of conductor structures is thus possible, which results in a reduction of the chip area and thus a reduction of the fabrication costs.

A further advantage of the present invention consists in the fact that the conversion of the preliminary structure into the conductor structure can be effected at a virtually arbitrary point in time after the production of the preliminary structure. In particular, it is possible in this way, for example, for components that are integrated jointly on a chip to be tested separately and only then to be electrically connected to one another by the conversion of the preliminary structures into conductor structures. This additional degree of freedom enables fabrication processes to be simplified and thus contributes to the reduction of fabrication costs.

Finally, a further advantage of the present invention consists in the fact that it is possible to provide integrated semiconductor circuits with numerous preliminary structures which represent options for the formation of different electrical connections and thus also different functionalities. Depending on the specific application for which the integrated semiconductor circuit is provided, it is then possible to select one or more of these options or functionalities. In order to realize the latter, only those preliminary structures which are necessary for the realization of the desired functionality are then converted into conductor structures. The present invention thus enables a new type of ASIC.

Preferred exemplary embodiments of the following invention are explained in more detail below with reference to the accompanying figures, in which:

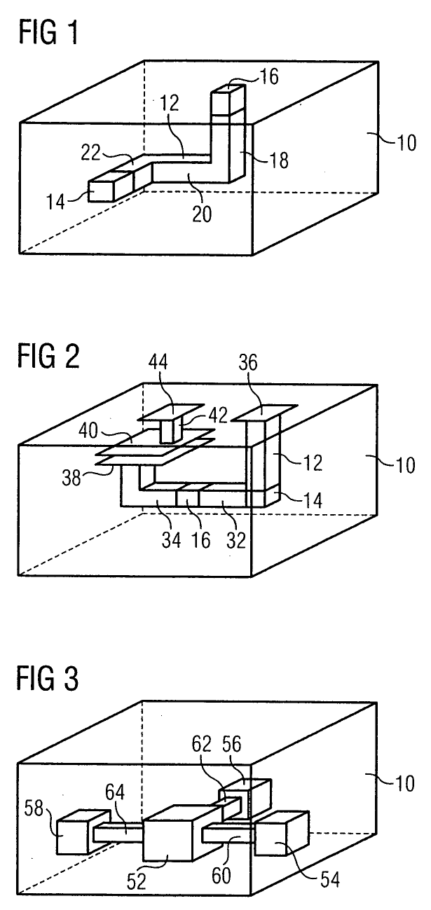

FIG. 1 shows a schematic perspective illustration of a preferred exemplary embodiment of the present invention;

FIG. 2 shows a schematic perspective illustration of a further preferred exemplary embodiment of the present invention;

FIG. 3 shows a schematic perspective illustration of a further exemplary embodiment of the present invention;

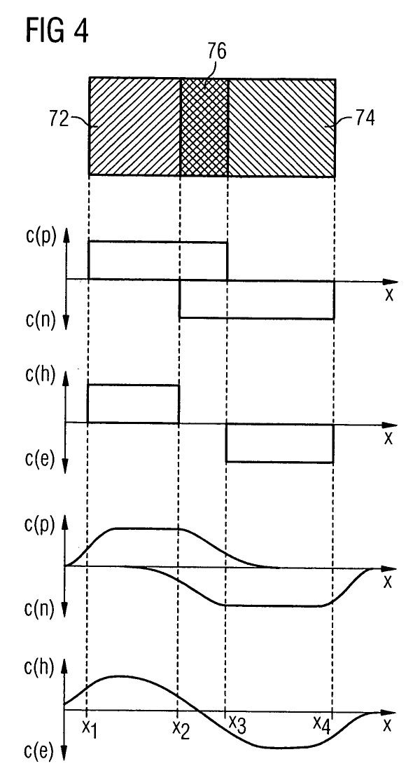

FIG. 4 shows a sectional view, doping profiles and charge carrier concentrations in a further preferred exemplary embodiment of the present invention;

FIG. 5 shows a schematic sectional illustration of a further preferred exemplary embodiment of the present invention;

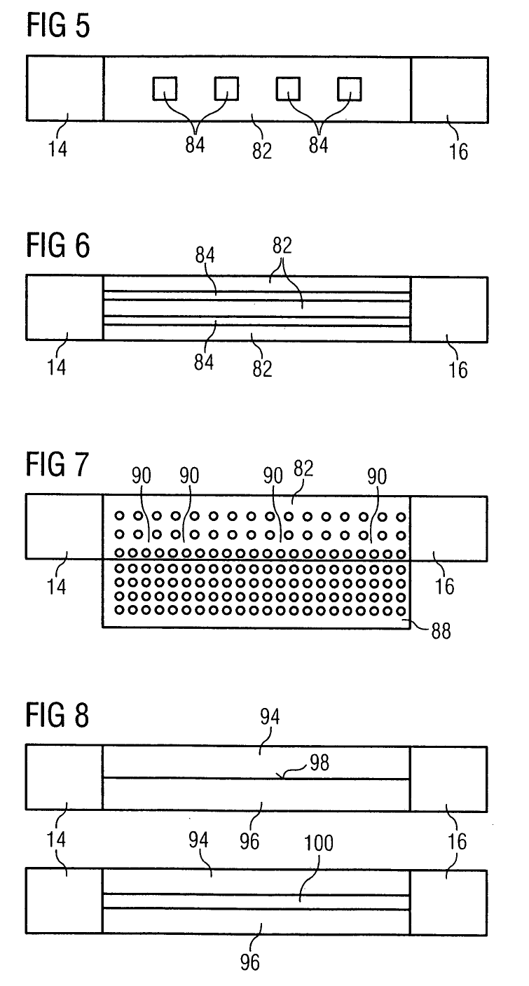

FIG. 6 shows a schematic sectional illustration of a further preferred exemplary embodiment of the present invention;

FIG. 7 shows a schematic sectional illustration of a further preferred exemplary embodiment of the present invention;

FIG. 8 shows a schematic sectional illustration of a further preferred exemplary embodiment of the present invention;

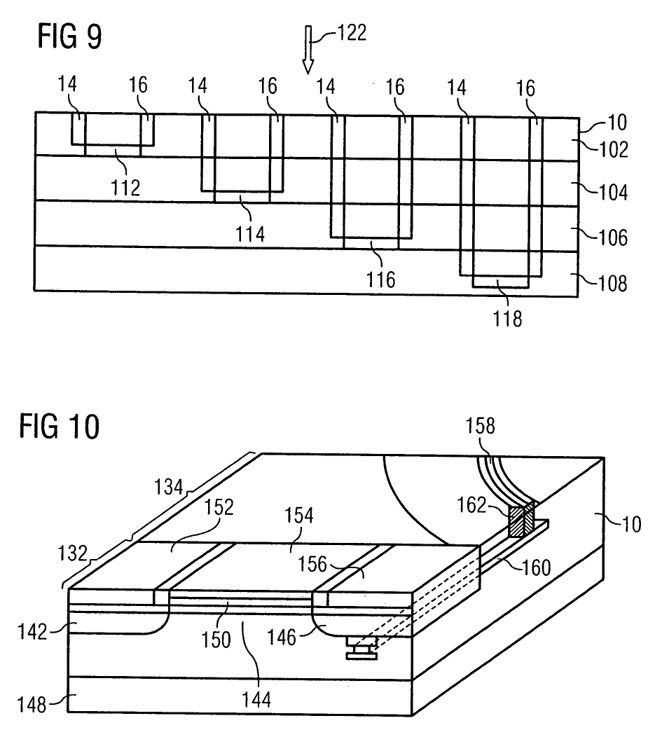

FIG. 9 shows a schematic sectional illustration of a further preferred exemplary embodiment of the present invention;

FIG. 10 shows a schematic perspective illustration of a further preferred exemplary embodiment of the present invention;

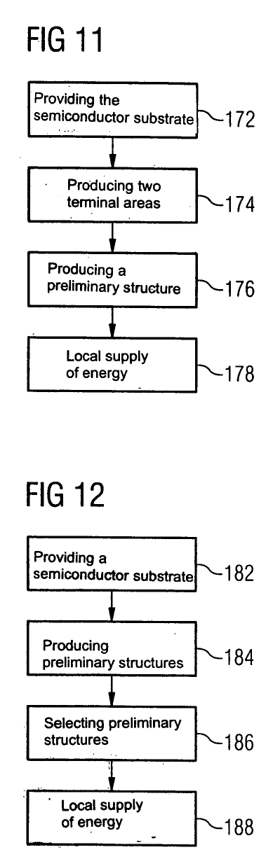

FIG. 11 shows a schematic flow diagram of a further preferred exemplary embodiment of the present invention; and

FIG. 12 shows a schematic flow diagram of a further preferred exemplary embodiment of the present invention.

FIG. 1 is a schematic perspective illustration of an integrated semiconductor circuit in accordance with a preferred exemplary embodiment of the present invention. A preliminary structure 12 is arranged in a semiconductor substrate 10. The parallelepiped indicated in perspective view represents a partial volume picked out more or less arbitrarily from the semiconductor substrate 10. It serves primarily for producing a spatial impression and represents possible surfaces of the semiconductor substrate. Form, size and arrangement of the surfaces of the semiconductor substrate may deviate from the illustration in FIG. 1. This applies in the same way to the illustrations in FIGS. 2, 3 and 10.

The preliminary structure 12 connects a first connection region 14 to a second connection region 16, which are likewise arranged in the semiconductor substrate 10. In this exemplary embodiment, the preliminary structure 12 has a vertical section 18 and two horizontal sections 20, 22 oriented essentially perpendicularly to one another.

The entire preliminary structure 12 or at least one section of the preliminary structure 12 has no or only a low electrical conductivity. It therefore forms no electrically conductive connection or a connection of low electrical conductivity between the connection regions 14, 16. By supplying energy to the preliminary structure 12, the latter can be converted into a conductor structure which forms an electrically conductive connection between the connection regions 14, 16 whose electrical conductivity is higher or preferably even substantially higher than the conductivity of the connection formed by the preliminary structure 12. The conversion of the preliminary structure 12 into the conductor structure is explained in more detail further below with reference to FIGS. 4 to 7.

The preliminary structure 12 and the connection regions 14, 16 are illustrated as parallelepipeds or as composed of parallelepipeds in FIG. 1. In a departure from this embodiment, the preliminary structure 12 and the connection regions 14, 16 may have arbitrary other geometrical forms. The preliminary structure 12 may, as illustrated in FIG. 1, comprise sections arranged parallel to the axes of a system of Cartesian coordinates. As an alternative or in addition, the preliminary structure 12 may have curved or arcuate sections or else sections arranged diagonally in the space.

The connection regions 14, 16 are likewise arranged arbitrarily within the semiconductor substrate 10. They are connection regions of electrical components, which are to include in particular also the electronic components, for example transistors, resistors, diodes, capacitors, inductive components, connection contact areas (pads) for electrical connection to other chips or to contact pins of a housing or conductor structures made of metal or doped semiconductor material. As an alternative, a connection region 14, 16 is part of a further preliminary structure arranged in series with the preliminary structure 12 illustrated in FIG. 1.

FIG. 2 is a schematic perspective illustration of an integrated semiconductor circuit in accordance with a further preferred exemplary embodiment of the present invention. A plurality of preliminary structures 12, 32, 34 connected in series are arranged in a semiconductor substrate 10. The first preliminary structure 12 connects a connection region 36, which here is a first connection contact area for producing a bonding connection, in the vertical direction to a second connection region 14 arranged underneath. The second preliminary structure 32 connects the second connection region 14 in the horizontal direction to a third connection region 16. The third preliminary structure 34 connects the third connection region 16 to a fourth connection region 38, which here is a capacitor electrode (oriented horizontally in this case). An opposite capacitor electrode 40 of the same capacitor is connected to a further connection contact area 44 via a conventional conductor structure 42.

The preliminary structures 12, 32, 34 originally have a low or no electrical conductivity. Initially no electrically conductive connection exists between the first connection contact area 36 and the first capacitor electrode 38. By locally supplying energy to the preliminary structures 12, 32, 34, the latter are converted into conductor structures, so that the first connection contact area 36 is electrically conductively connected to the first capacitor electrode 38, or is connected with a higher electrical conductivity than originally via the preliminary structures 12, 32, 34.

The exemplary embodiment illustrated in FIG. 2 shows that a plurality of conductor structures in accordance with the present invention can be combined with one another in the form of an electrical series circuit in order to form, after the conversion into conductor structures, electrically conductive connections between electrical or electronic components. The preliminary structures 12, 32, 34 may be converted into conductor structures either jointly or simultaneously or at the same time, or successively. The second connection region 14 and the third connection region 16 are either conventionally fabricated conductor regions or else merely symbolize boundaries or transition regions between the preliminary structures 12, 32, 34. The preliminary structures 12, 32, 34 are produced either at the same time by means of the same process steps or successively by means of corresponding or different process steps. As a result, they may differ both in their structure and in the type of conversion to the conductor structure and in their electrical properties and the electrical properties of the conductor structures produced from them.

In a departure from the exemplary embodiment illustrated in FIG. 2, a structure made of a plurality of preliminary structures may furthermore have branchings in accordance with the present invention.

FIG. 3 is a schematic perspective illustration of an integrated semiconductor circuit in accordance with a further preferred exemplary embodiment of the present invention. Four electrical or electronic components 52, 54, 56, 58 are arranged in the semiconductor substrate 10, each of which components may be part of a subcircuit (not illustrated) in the semiconductor substrate 10. The first component 52 is connected to a respective one of the other three components 54, 56, 58 via preliminary structures 60, 62, 64. Connection regions of the preliminary structures 60, 62, 64 are here preferably at the same time connection regions of the components 52, 54, 56, 58. They are not illustrated in FIG. 3.

The integrated semiconductor circuit illustrated as a partial detail in FIG. 3 can be adapted to different specific applications and the requirement profile thereof in a simple manner. For this purpose, one or two of the three preliminary structures 60, 62, 64 are selected and converted into conductor structures by the local supply of energy or all three preliminary structures 60, 62, 64 are converted into conductor structures. The integrated semiconductor circuit has different electrical properties or different functionalities depending on that component or those components from among the components 54, 56, 58 to which the first component 52 is electrically conductively connected. The integrated semiconductor circuit can thus readily be adapted for example to specific signal impedances, signal levels, an available input power, an output power that is to be output, a clock frequency, etc. Instead of one preliminary structure in each case, as an alternative a plurality of preliminary structures arranged in series in each case are provided, in a similar manner to that shown in FIG. 2.

By way of example, the components 54, 56, 58 are input amplifiers or parts of input amplifiers having a different sensitivity, different dynamic range, different gain and/or different power consumption which are arranged in parallel in signal paths and can be activated by conversion of the corresponding preliminary structure 60, 62, 64 into a conductor structure. This activation takes place for example by supplying them with electrical power via the conductor structure that has emerged from the preliminary structure. As an alternative, the preliminary structures 60, 62, 64 are part of the input signal path, so that the input signal can be supplied to one or more selected preamplifiers for amplification.

What is common to the exemplary embodiments illustrated in FIGS. 1 to 3 is that the preliminary structures 12, 32, 34, 60, 62, 64 are arranged such that they are buried in the semiconductor substrate 10. A preliminary structure is buried in the sense of this text when it is arranged in a manner spaced apart from all surfaces of the semiconductor substrate 10 at least in sections.

Examples of a realization of the preliminary structures 12, 32, 34, 60, 62, 64 are illustrated below with reference to FIGS. 4 to 7. Each exemplary embodiment of the preliminary structure may be particularly suitable for a different geometry of the preliminary structure. However, it is noted that all of the geometrical proportions illustrated in FIGS. 1 to 7 merely represent examples and consequently, in principle, each of the exemplary embodiments of the preliminary structure that are illustrated in FIGS. 4 to 7 can be used for each geometry and, in particular, also each of the geometries illustrated in FIGS. 1 to 3.

FIG. 4 illustrates one above the other from top to bottom a plan view of the preliminary structure, dopant concentrations and resulting charge carrier densities in the same and also dopant concentrations and charge carrier density after the conversion of the preliminary structure into a conductor structure. Although the dopant concentrations and charge carrier densities are illustrated in idealized or simplified fashion, they enable a good understanding of the conversion of the preliminary structure into a conductor structure.

A p-doped region 72 illustrated in right-hatched fashion in FIG. 4 extends in the x direction from x₁ to x₃. An n-doped region 74, which is left-hatched in FIG. 4, extends in the x direction from x₂ to x₄. The p-doped region 72 and the n-doped region 74 overlap in an overlap region 76 extending from x₂ to x₃. The concentration c(p) of the acceptors in the p-doped region 72 and the concentration c(n) of the donors in the n-doped region 74 are chosen such that they compensate for one another at least in the overlap region 76. For this purpose, the concentrations c(p) of the acceptors and c(n) of the donors are in the simplest case identical in magnitude in the overlap region 76. The concentrations of the holes c(h) and of the electrons c(e) therefore vanish to an approximation in the overlap region 76. Consequently, an extremely low, to an approximation vanishing electrical conductivity results in the overlap region 76 in the preliminary structure.

If the entire region occupied by the p-doped region 72 and the n-doped region 74 is considered as preliminary structure, the latter has a section of low electrical conductivity, namely the overlap region 76. As an alternative, merely the overlap region 76 may be considered as preliminary structure, while the sections of the p-doped region 72 and of the n-doped region 74 that lie outside the overlap region 76 represent connection regions in a manner similar, for example, to the connection regions 14, 16 illustrated in FIGS. 1 and 2. In this consideration, the entire preliminary structure is electrically nonconductive or has a low electrical conductivity.

If energy is supplied to the preliminary structure leading to heating thereof, the dopants of the p-doped region 72 and of the n-doped region 74 diffuse. After the diffusion, dopant profiles are established such as are illustrated on the second x axis from the bottom in FIG. 4. The concentrations of the donor atoms and of the acceptor atoms are altered to different extents as a result of the diffusion since the dopant profiles and the diffusion properties of the donors and the acceptors differ. The concentration c(p) of the acceptors from the p-doped region 72 and the concentration c(n) of the donors from the n-doped region 74 now no longer compensate for one another in the entire region between x₂ and x₃, but rather only at a single x coordinate. Concentrations c(h) of the holes and c(e) of the electrons result such as are illustrated right at the bottom in FIG. 4 without taking account of a depletion zone. It can clearly be discerned that now an electrically insulating overlap region 76 is no longer present, but rather a pn junction that is conductive upon application of a low voltage in the forward direction.

FIG. 5 is a schematic sectional illustration of a preliminary structure in accordance with a further exemplary embodiment of the present invention. An undoped or weakly doped, contiguous semiconductor region 82 is arranged between a first connection region 14 and a second connection region 16. The semiconductor region 82 adjoins both connection regions 14, 16. Insulator regions 84 containing a dopant are arranged in the semiconductor region 82. The undoped or weakly doped semiconductor region 82 has a low electrical conductivity.

If the preliminary structure illustrated in FIG. 5 is heated by supplying energy, dopant diffuses from the insulator regions 84 into the semiconductor region 82. The distances between the insulator regions 84 and also between the insulator regions 84 and the connection regions 14, 16, on the one hand, and the temperature and duration of the heating brought about by the supply of energy, on the other hand, are chosen in such a way that at least one path between the connection regions 14, 16 arises in the semiconductor region 82 and ensures a desired conductivity between the connection regions 14, 16 on account of a sufficiently high dopant concentration. This condition is fulfilled for example when the distances between the connection regions 14, 16, on the one hand, and the respectively nearest insulator regions 84, on the other hand, are less than or equal to a diffusion length of the dopant during the local heating and the distances between the insulator regions 84 are less than or equal to twice the diffusion length. In this case, the term diffusion length preferably denotes the linearly or quadratically averaged distance between a dopant atom and its starting location after the diffusion caused by the heating of the preliminary structure.

FIG. 6 is a schematic sectional illustration of a preliminary structure in accordance with a further exemplary embodiment of the present invention. In a manner similar to that in the case of the exemplary embodiment illustrated with reference to FIG. 5, a semiconductor region 82 is arranged between connection regions 14, 16. Insulator regions 84 are now not arranged in the form of islands but rather in the form of layers in the semiconductor region 82. The layered insulator regions 84 may be arranged virtually arbitrarily in the semiconductor region 82, but at least one contiguous partial region of the semiconductor region 82 which adjoins both connection regions 14, 16 must exist.

In a similar manner to that in the case of the exemplary embodiment illustrated with reference to FIG. 5, the semiconductor region 82 in the preliminary structure forms merely a connection of low electrical conductivity between the connection regions 14, 16. The preliminary structure is heated by local supply of energy, and dopant diffuses from the insulator regions 84 into the semiconductor region 82. As a result, the electrical conductivity thereof is drastically increased, and the semiconductor region 82 then forms an electrically conductive connection between the connection regions 14, 16.

FIG. 7 is a schematic sectional view of a preliminary structure in accordance with a further exemplary embodiment of the present invention. Arranged between connection regions 14, 16 is a semiconductor region 82, which is contiguous and adjoins both connection regions 14, 16. The semiconductor region 82 furthermore adjoins a crystalline region 88, which has a different crystal lattice structure, in particular crystal lattice constant, than the semiconductor region 82. This lattice mismatch results in crystal lattice defects 90 in the semiconductor region 82. The crystal lattice defects 90 reduce the mobility of charge carriers in the semiconductor region 82. Furthermore, localized electron/hole states to which free charge carriers are bound exist at the crystal lattice defects 90. The crystal lattice defects 90 reduce the number of free charge carriers in this way. Consequently, the crystal lattice defects 90 overall reduce the electrical conductivity of the semiconductor region 82.

An annealing of the crystal lattice defects 90 is brought about as a result of the semiconductor region 82 being heated on account of a local supply of energy. As a result, the mobility and the number of free charge carriers and thus also the electrical conductivity of the semiconductor region 82 are increased.

As an alternative, a lattice mismatch that leads to a formation of crystal lattice defects does not exist between the semiconductor region 82 and the separately provided crystalline region 88, but rather between the semiconductor region 82 and one of the connection regions 14, 16 or both connection regions 14, 16.

In accordance with a further variant, the semiconductor region 82 is produced in polycrystalline fashion, the grain boundaries forming the crystal lattice defects. During the local supply of energy and the resulting heating, the grains are enlarged, as a result of which the number of crystal lattice defects decreases. In the extreme case, the local supply of energy produces a quasi-monocrystalline structure of the semiconductor region 82 which almost no longer has any crystal lattice defects in comparison with the polycrystalline structure.

In accordance with a further variant of the present invention, the semiconductor region 82 is originally produced in amorphous fashion. During the local supply of energy, the preliminary structure is converted into the conductor structure by the amorphous structure of the semiconductor region 82 being converted into a crystalline or polycrystalline structure. This is accompanied by a drastic increase in the electrical conductivity.

FIG. 8 is a schematic sectional illustration of a preliminary structure (top) in accordance with a further exemplary embodiment of the present invention and of a conductor structure that has emerged therefrom (bottom). The preliminary structure comprises two mutually adjoining regions 94, 96 with two different materials which in each case have no or only a vanishing electrical conductivity and adjoin both connection structures 14, 16. A local supply of energy and a resulting heating of the regions 94, 96 bring about a diffusion of the materials thereof and an intermixing of the same at an interface 98 between the regions 94, 96. A layer 100 comprising a mixture of the two materials of the regions 94, 96 therefore forms between the regions 94, 96. The materials of the regions 94, 96 are chosen in such a way that the mixture of the two materials has an electrical conductivity, so that the layer 100 forms an electrically conductive connection between the connection regions 14, 16.

The previous description of the exemplary embodiments of the integrated semiconductor circuit and of the preliminary structures in the integrated semiconductor circuits has not yet described in greater detail how the local supply of energy for converting the preliminary structure into the conductor structure is effected. A plurality of possibilities exist for this purpose in all of the exemplary embodiments described previously; these possibilities are explained below.

The local supply of energy is effected in a particularly advantageous manner by means of electromagnetic radiation that is generated by a laser or a non-coherent radiation source. The electromagnetic radiation is preferably supplied selectively essentially only to the preliminary structure, or focused onto the latter, by means of a mask and/or by means of an optical imaging system. In the case of focusing the electromagnetic radiation, the location of the focus is preferably oriented not only laterally but also vertically to the preliminary structure. A preliminary structure which is larger than the focus has energy supplied to it in a plurality of steps in each case after displacement of the focus. As an alternative, the focus is moved continuously in order to supply energy to the entire preliminary structure.

The photon energy of the electrical radiation is preferably chosen in such a way that the photons are absorbed only in the preliminary structure and not, or only to a substantially lesser extent, in surrounding material.

In the case of the exemplary embodiments illustrated above, the supply of energy effects a local heating of the preliminary structure, which then results in the conversion of the preliminary structure into the conductor structure. As an alternative, the electromagnetic radiation does not effect the conversion of the preliminary structure into the conductor structure in a thermal manner, but rather for example in a photochemical manner.

Either thermally or photochemically, the electromagnetic radiation, in accordance with a further exemplary embodiment, effects a recrystallization or a chemical conversion of the preliminary structure into the conductor structure.

A local supply of energy for converting the preliminary structure into the conductor structure in accordance with the present invention is furthermore possible by means of (focused) ultrasound, by means of particle radiation or in some other way. In this case, too, the wavelength or frequency of the ultrasound or the type or energy of the particle radiation is coordinated with the preliminary structure in such a way that an absorption of energy takes place exclusively or with substantially higher probability in the preliminary structure than in surrounding material.

FIG. 9 is a schematic sectional illustration of a part of an integrated semiconductor circuit in accordance with a further exemplary embodiment of the present invention. A semiconductor substrate 10 comprises a plurality of layers 102, 104, 106, 108, in each of which one or more preliminary structures 112, 114, 116, 118 are arranged. Each of the preliminary structures 112, 114, 116, 118 adjoins in each case two connection regions 14, 16. On account of the material from which it is formed or on account of the material of the layer 102, 104, 106, 108 in which it is formed, each of the preliminary structures 112, 114, 116, 118 has a different “activation energy” or photon energy at which a conversion of the preliminary structure into a conductor structure takes place.

Electromagnetic energy, for example in the form of UV or IR light, is radiated onto the semiconductor substrate 10 in the direction of the arrow 122. A selection of the preliminary structure 112, 114, 116, 118 which is to be activated or converted into a conductor structure can now be effected not only by means of a lateral intensity modulation but also by means of the photon energy of the electromagnetic radiation that is radiated in.

FIG. 10 is a schematic perspective illustration of an integrated semiconductor circuit in accordance with a further exemplary embodiment of the present invention. This exemplary embodiment shows an application of the present invention in which, within a semiconductor substrate 10, analog and/or digital VLSI-CMOS circuits (VLSI=Very Large Scale Integration; CMOS=Complementary Metal Oxide Semiconductor) are integrated in a first section 132 and an integrated radiofrequency circuit is integrated in a second section 134.

In this example, the VLSI CMOS circuit is represented by a field effect transistor having a source region 142, a channel region 144 and a drain region 146 in a p-doped well 148 and also a gate oxide 150, a source connection region 152, a gate electrode 154 and a drain connection region 156. The integrated radio frequency circuit in the second section 134 is represented by a microstripline 158. The microstripline enables a good control or setting of the impedance, geometrical distance parameters or the surrounding dielectric being a function of the three-dimensional dopant concentration profile and of the lithography process used during production. Arranged beneath the drain region 146 is a buried stripline 160, or stripline 160 spaced apart from the surface of the semiconductor substrate 10. For simplification, the insulator strips of the stripline 160 are shown only at the sectional area of the semiconductor substrate 10 illustrated at the front.

A conductor structure 162 is provided between the microstripline 158 and the stripline 160, which conductor structure, as illustrated in the exemplary embodiments above, has been formed from a preliminary structure. The microstripline 158 and the stripline 160 thus form connection regions of the conductor structure 162 or of the preliminary structure from which the conductor structure 162 has emerged. Although the conductor structure 162 is illustrated with a very simple parallelepipedal structure oriented vertically in FIG. 10, it may, as illustrated above, have an arbitrary geometrical shape in order to enable, in conjunction with optimum signal transmission properties, a maximally space-saving arrangement of the integrated radio frequency circuit and the VLSI CMOS circuit thereof. Furthermore, the conductor structure 162 may be produced from a preliminary structure selected from a plurality of preliminary structures depending on the application for which the integrated semiconductor circuit is provided, in order to optimally adapt its electrical properties to the envisaged application.

FIG. 11 is a schematic flow diagram illustrating the method according to the invention for fabricating an integrated semiconductor circuit. A first step 172 involves providing the semiconductor substrate, in which at least two connection regions are formed in a second step 174. A third step 176 involves forming a preliminary structure, which is converted into a conductor structure by local supply of energy in a fourth step 178. The second step 174 and the third step 176 and also further steps (not illustrated) may be performed in an arbitrary order so as to produce an integrated semiconductor circuit according to the invention with a preliminary structure. The fourth step 178 may be effected as soon as the preliminary structure has been formed in the third step 176, but is preferably effected only at the end of the fabrication process once all or almost all other fabrication steps have been concluded.

FIG. 12 shows a schematic flow diagram of a fabrication method for an application specific integrated semiconductor circuit in accordance with another exemplary embodiment of the present invention. A first step 182 involves providing a semiconductor substrate, in which preliminary structures are formed in a second step 184. In a third step 186, one or more preliminary structures are selected depending on an application for which the application specific integrated semiconductor circuit is provided, which preliminary structures are converted into one or more conductor structures, respectively, by local supply of energy in a fourth step 188. The first two steps 182, 184 are part of a fabrication process whose result is an integrated semiconductor circuit in accordance with the present invention, which may then be kept in a store or else be delivered to a customer. The third step 186 and the fourth step 188 may take place at an arbitrary later point in time on the premises of the manufacturer of the integrated semiconductor circuit or else on the customer's premises in order to adapt the integrated semiconductor circuit to a specific application. In this case, the preliminary structure or the preliminary structures are selected in such a way that desired properties and functionalities of the integrated semiconductor circuit are realized.

As demonstrated by the exemplary embodiments above, the present invention can be realized both as a fabrication method and as an integrated semiconductor circuit. In particular, each of the methods illustrated above with reference to FIGS. 11 and 12 is advantageous and readily adaptable for fabricating one of the exemplary embodiments illustrated with reference to FIGS. 1 to 10.

1. A method for fabricating an integrated semiconductor circuit having a conductor structure buried in a semiconductor substrate, which conductor structure electrically conductively connects two connection regions comprising:
providing the semiconductor substrate;
producing the two connection regions;
producing a preliminary structure, buried in the semiconductor substrate, for the conductor structure between the two connection regions, the preliminary structure forming no electrically conductive connection or a connection of low electrical conductivity between the connection regions; and
locally supplying energy to the preliminary structure to convert the preliminary structure into the conductor structure, the conductor structure forming a connection between the connection regions whose electrical conductivity is higher than the conductivity of the connection formed by the preliminary structure.

2. A method for fabricating an integrated semiconductor circuit having an electrically conductive connection between a first electrical component and a second electrical component comprising:
producing a conductor structure or a plurality of series-connected conductor structures which connect the first electrical component to the second electrical component, the production comprising:
providing a semiconductor substrate;
producing two connection regions;
producing a preliminary structure, buried in the semiconductor substrate, for the conductor structure between the two connection regions, the preliminary structure forming no electrically conductive connection or a connection of low electrical conductivity between the connection regions; and
locally supplying energy to the preliminary structure to convert the preliminary structure into the conductor structure, the conductor structure forming a connection between the connection regions whose electrical conductivity is higher than the conductivity of the connection formed by the preliminary structure.

3. A method for fabricating an integrated semiconductor circuit having a conductor structure buried in a semiconductor substrate, which conductor structure electrically conductively connects two connection regions comprising:
providing the semiconductor substrate;
producing the two connection regions;
producing a preliminary structure, buried in the semiconductor substrate, for the conductor structure between the two connection regions, the preliminary structure forming no electrically conductive connection or a connection of low electrical conductivity between the connection regions; and
local supply of energy to the preliminary structure to convert the preliminary structure into the conductor structure, the conductor structure forming a connection between the connection regions whose electrical conductivity is higher than the conductivity of the connection formed by the preliminary structure,
the preliminary structure being produced by production of a p-doped region and an n-doped region that overlaps the p-doped region in an overlap region,
the p-type doping and the n-type doping compensating for one another in the overlap region prior to the local supply of energy, so that no free charge carriers are present, and
the preliminary structure being converted into the conductor structure by the concentrations of the dopants being altered to different extents in the overlap region by diffusion.

4. A method for fabricating an application specific integrated semiconductor circuit, comprising:
providing a semiconductor substrate with a plurality of electrical components;
producing a plurality of preliminary structures buried in the semiconductor substrate, each preliminary structure forming no electrically conductive connection or a connection of low electrical conductivity between two assigned connection regions;
selecting one or more of the preliminary structures depending on an application for which the semiconductor circuit is provided; and
locally supplying energy to the one or more selected preliminary structures to convert the latter into a conductor structure or conductor structures which in each case form a connection between the assigned connection regions, the electrical conductivity of each conductor structure being higher than the conductivity of the connection formed by the preliminary structure, as a result of which two electrical components are electrically conductively connected to one another.

5. The method as claimed in claim 4,
in which the preliminary structure is produced by production of a p-doped region and an n-doped region that overlaps the p-doped region in an overlap region,
the p-type doping and the n-type doping compensating for one another in the overlap region prior to the local supply of energy, so that no free charge carriers are present, and
in which the preliminary structure is converted into the conductor structure by the concentrations of the dopants being altered to different extents in the overlap region by diffusion.

6. The method as claimed in claim 1,
in which the preliminary structure is produced by production of an insulator region, which includes a dopant, and an adjoining semiconductor region, which is contiguous and adjoins both connection regions, and
in which, during the local supply of energy, the dopant diffuses from the insulator region into the semiconductor region, so that the electrical conductivity thereof is increased.

7. The method as claimed in claim 6,
in which the insulator region is produced such that its distance from each of the two connection regions is at most as large as the diffusion length of the dopant during the local supply of energy.

8. The method as claimed in claim 7, in which the insulator region is produced such that it comprises a plurality of partial insulator regions whose distances from one another are at most as large as twice the diffusion length of the dopant during the local supply of energy.

9. The method as claimed in claim 6, in which the insulator region is formed from one or more thin layers arranged in the semiconductor region.

10. The method as claimed in claim 1,
in which the preliminary structure is produced by production of a doped semiconductor region with crystal lattice defects, which is contiguous and adjoins both connection regions, and
in which the preliminary structure is converted into the conductor structure by annealing of the crystal lattice defects during the local supply of energy.

11. The method as claimed in claim 10, in which the crystal lattice defects are produced on account of a lattice mismatch with an adjoining crystalline material.

12. The method as claimed in claim 11, in which the local supply of energy effects a chemical conversion of the preliminary structure into the conductor structure.

13. The method as claimed in claim 1, in which the local supply of energy effects a change in the crystal structure of the preliminary structure to the crystal structure of the conductor structure.

14. The method as claimed in claim 13, in which the change in the crystal structure is a recrystallization.

15. The method as claimed in claim 1, in which the preliminary structure is produced in amorphous fashion, and in which the conductor structure emerges from the preliminary structure by means of a crystallization during the local supply of energy.

16. The method as claimed in claim 1, in which the preliminary structure is formed from two mutually adjoining regions with two different materials, and in which the conductor structure arises during the local supply of energy as a result of a mixing of the two materials at the interface.

17. The method as claimed in claim 1, in which the energy is supplied locally by electromagnetic radiation whose photons are absorbed in the preliminary structure.

18. The method as claimed in claim 17, in which material of the semiconductor substrate that surrounds the preliminary structure does not absorb the photons of the electromagnetic radiation or absorbs them less than the preliminary structure.

19. The method as claimed in claim 17, in which the electromagnetic radiation is focused onto the preliminary structure.

20. The method as claimed in claim 17, in which the electromagnetic radiation is guided selectively onto the preliminary structure by means of a mask.

21. An integrated semiconductor circuit, comprising:
a semiconductor substrate;
two connection regions in the semiconductor substrate; and
a preliminary structure buried in the semiconductor substrate, which preliminary structure forms no electrically conductive connection or a connection of low electrical conductivity between the connection regions, and which preliminary structure can be converted into a buried conductor structure by local supply of energy, which buried conductor structure forms a connection between the two connection regions whose electrical conductivity is higher than the electrical conductivity of the connection formed by the preliminary structure.

22. The integrated semiconductor circuit as claimed in claim 21, further comprising a plurality of preliminary structures, the integrated semiconductor circuit configured to be adapted to an application by selection of a preliminary structure and local supply of energy to the selected preliminary structure.

23. The integrated semiconductor circuit as claimed in claim 21, in which the preliminary structure comprises a p-doped region and an n-doped region that overlaps the p-doped region in an overlap region,
the p-type doping and the n-type doping compensating for one another in the overlap region, so that no free charge carriers are present.

24. The integrated semiconductor circuit as claimed in claim 21, in which the preliminary structure comprises an insulator region, which includes a dopant, and an adjoining semiconductor region, which is contiguous and adjoins both connection regions.
